(19) United States
(12) Patent Application Publication
(10) Pub. No.: US 2023/0174142 A1
(43) Pub. Date: Jun. 8, 2023

(54) STEERING SYSTEM

(71) Applicant: HL MANDO CORPORATION, Gyeonggi-do (KR)

(72) Inventor: NamGyun KIM, Gyeonggi-do (KR)

(21) Appl. No.: 18/075,401

(22) Filed: Dec. 5, 2022

(30) Foreign Application Priority Data
Dec. 6, 2021 (KR) 1020210173212

(51) Int. Cl. B62D 5/04; H02M 1/12; H02M 1/44; H03H 7/01; H02M 1/14

(52) U.S. Cl. CPC B62D 5/046; H02M 1/126; H02M 1/123; H02M 1/44; H03H 7/0153; H02M 1/143

(57) ABSTRACT

The embodiments relate to a steering system. A steering system according to an embodiment may include a steering assistance device configured to assist a steering device positioned between a steering wheel and a wheel, and a noise reduction device configured to reduce noise of the steering system with the steering assistance device.

### CROSS REFERENCE TO RELATED APPLICATION

This application claims priority from Korean Patent Application No. 10-2021-0173212, filed on Dec. 6, 2021, which is hereby incorporated by reference for all purposes as if fully set forth herein.

### TECHNICAL FIELD

Embodiments of the present disclosure relate to a steering system.

In general, a steering system refers to a system capable of changing a steering angle of a wheel based on a steering force (or rotational force) applied to a steering wheel by a driver of a vehicle. Recently, an electric power steer (EPS), that is, an electric power steering system, has been applied to vehicles in order to reduce the steering force of a steering wheel to ensure the stability of a steering state.

In particular, in recent years, there has increased the demand for research and development on noise improvement for a steering system of a vehicle.

### SUMMARY

An embodiment of the present disclosure is to provide a steering system capable of reducing noise and increasing reliability.

In an aspect of the present disclosure, there is provided a steering system including a steering assistance device configured to assist a steering device positioned between a steering wheel and a wheel, and a noise reduction device configured to reduce noise of the steering system with the steering assistance device, wherein the noise reduction device comprises a virtual ground, and wherein the virtual ground enables a second noise path having a lower impedance than a first noise path through which noise flowing into the steering assistance device flows to be formed on the steering system.

In another aspect of the present disclosure, there is provided a steering system including a steering assistance device configured to assist a steering device positioned between a steering wheel and a wheel, and a noise reduction device configured to reduce noise of the steering system including the steering assistance device, wherein the noise reduction device comprises a filter structure, and wherein the filter structure is located between the steering device and the steering assistance device to filter noise flowing out from the steering assistance device.

In another aspect of the present disclosure, there is provided a steering system including a steering assistance device configured to assist a steering device positioned between a steering wheel and a wheel, and a noise reduction device configured to reduce noise of the steering system with the steering assistance device, wherein the noise reduction device comprises a virtual ground and a filter structure, wherein the virtual ground enables a second noise path having a lower impedance than a first noise path through which noise flowing into the steering assistance device flows to be formed on the steering system, and wherein the filter structure is located between the steering device and the steering assistance device to filter noise flowing out from the steering assistance device.

According to embodiments of the steering system according to the present disclosure, it is possible to provide a steering system capable of reducing noise and increasing reliability.

### BRIEF DESCRIPTION OF THE DRAWINGS

FIGS. 1 and 2 are block diagrams for explaining a steering system according to the present embodiments.

FIGS. 3 and 4 are diagrams for explaining a steering device according to the present embodiments.

FIG. 5 is a block diagram illustrating a steering assistance device according to the present embodiments.

FIG. 6 is a block diagram illustrating a steering control module according to the present embodiments.

FIG. 7 is a block diagram illustrating a noise reduction device according to the present embodiments.

FIG. 8 is a diagram for explaining noise in the steering system according to the present embodiments.

FIG. 9 is a diagram for explaining a noise improvement method using a virtual ground according to the present embodiments.

FIG. 10 is a diagram for explaining a noise improvement method using a filter structure according to the present embodiments.

FIG. 11 is a diagram for explaining a noise improvement method using a first filter structure according to the present embodiments.

FIG. 12 is a diagram for explaining a noise improvement method using a second filter structure and a third filter structure according to the present embodiments.

FIG. 13 is a block diagram of a computer system of a steering control device, a steering assistance device, and a steering system according to the present embodiments.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The tams such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Tams, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these tams may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

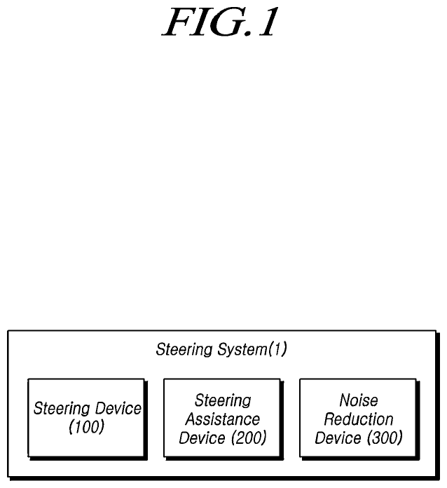

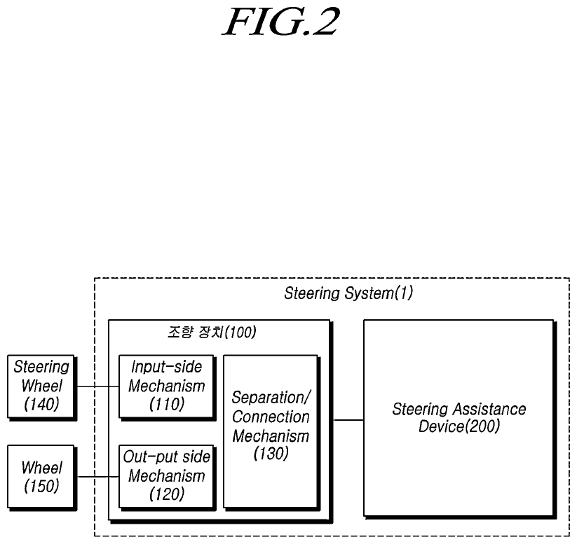

FIGS. 1 and 2 are block diagrams for explaining a steering system according to the present embodiments.

Referring to FIG. 1, a steering system 1 according to the present embodiments may include at least one of a steering device 100, a steering assistance device 200 and a noise reduction device 300.

The steering device 100, the steering assistance device 200 and the noise reduction device 300 may be connected to each other. Each of the steering device 100, the steering assistance device 200 and the noise reduction device 300 may be one or plural.

Referring to FIG. 2, the steering device 100 may change a steering angle of a wheel 150 based on a steering force (or rotational force, etc.) applied to a steering wheel

The steering device 100 may include at least one of an input-side mechanism 110, an output-side mechanism 120, and a separation/connection mechanism 130.

The input-side mechanism 110 may be connected to the steering wheel 140. The input-side mechanism 110 may rotate in a rotational direction of the steering wheel 140 or in a direction opposite to the rotational direction of the steering wheel 140.

The output-side mechanism 120 may be connected to the input-side mechanism 110 and the wheel 150. The output-side mechanism 120 may change the steering angle (or movement, etc.) of the wheel 150.

The separation/connection mechanism 130 may be located between the input-side mechanism 110 and the output-side mechanism 120, and may mechanically and/or electrically connect or separate the input-side mechanism 110 and the output-side mechanism 120.

The separation/connection mechanism 130 may include a clutch, but is not limited thereto, and may include another mechanism (or device) capable of mechanically and/or electrically connecting and/or separating the input-side mechanism and the output-side mechanism.

The steering assistance device 200 may be connected to the steering device 100. The steering assistance device 200 may assist the steering device 100.

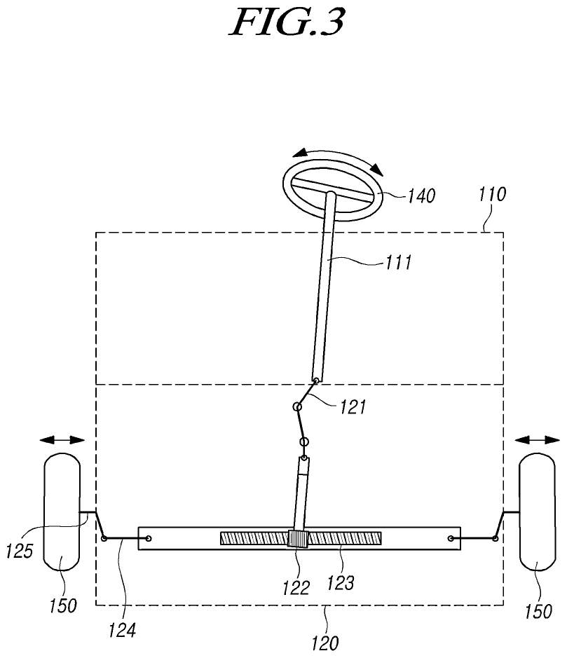

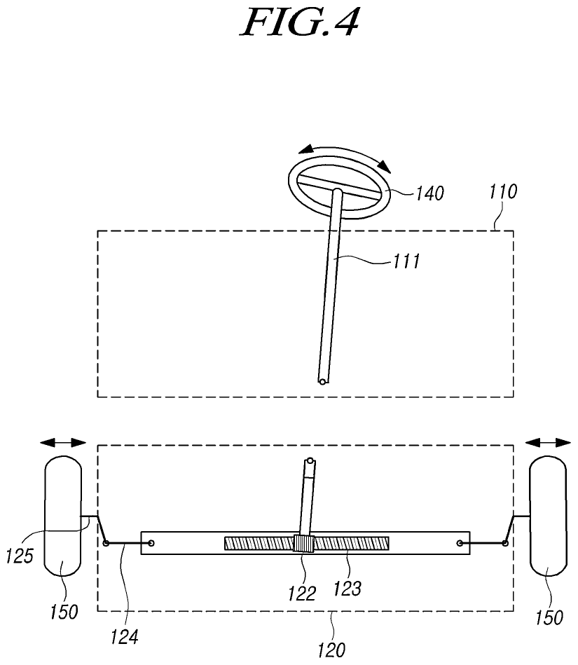

FIGS. 3 and 4 are diagrams for explaining a steering device according to the present embodiments.

Referring to FIG. 3, the steering device 100 according to the present embodiments may include a steering device in which the input-side mechanism 110 and the output-side mechanism 120 are mechanically connected.

That is, the steering device 100 according to the present embodiments may include an input-side mechanism 110 connected to a steering wheel 140; and at least one of an output-side mechanism 120 mechanically connected to the input-side mechanism 110 and connected to the wheel 150.

Referring to FIG. 4, the steering device 100 according to the present embodiments may include a steering device in which an input-side mechanism 110 and an output-side mechanism 120 are electrically connected. That is, the steering device 100 according to the present embodiments may include a steer-by-wire (SbW) steering device.

That is, the steering device 100 according to the present embodiments may include at least one of an input-side mechanism 110 connected to a steering wheel 140, and an output-side mechanism 120 mechanically separated from the input-side mechanism 110 and connected to the wheel 150.

Meanwhile, the steering device 100 according to the present embodiments may include a steering device in which the input-side mechanism 110 and the output-side mechanism 120 are connected to the separation/connection device 130. That is, the steering device 100 according to the present embodiments may include a steer-by-wire (SbW) steering device including a clutch.

That is, the steering device 100 according to the present embodiments may include an input-side mechanism 110 connected to a steering wheel 140, an output-side mechanism 120 mechanically separated from the input-side mechanism 110 and connected to the wheel 150, and a separation/connection mechanism 130 that mechanically and/or electrically connects or separates the input-side mechanism 110 and the output-side mechanism 120. Referring to FIGS. 3 and 4, the input-side mechanism 110 may include a steering shaft 111 connected to the steering wheel 140, but is not limited thereto, and may include any mechanism (or device) capable of rotating (or moving) in the rotational direction of the steering wheel or in the direction opposite to the rotational direction of the steering wheel.

The output-side mechanism 120 may include at least one of a pinion 122, a rack 123, a tie rod 124, and a knuckle arm 125. However, it is not limited thereto, and may include any mechanism (or device) capable of changing the steering angle (or movement, etc.) of the wheel.

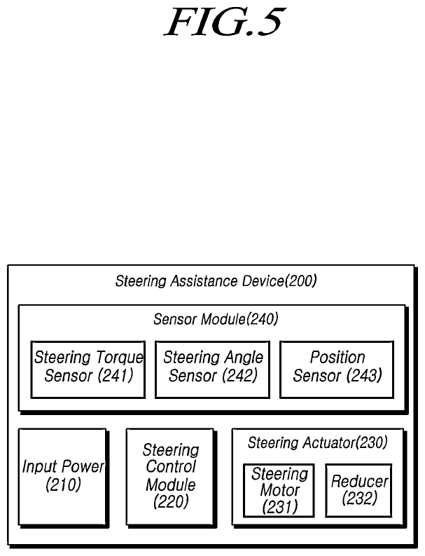

FIG. 5 is a block diagram illustrating a steering assistance device according to the present embodiments.

Referring to FIG. 5, the steering assistance device 200 according to the present embodiments may assist and/or control at least one of the input-side mechanism 110, the output-side mechanism 120 and the separation/connection mechanism 130.

For example, the steering assistance device 200 may provide assist steering force to at least one of the input-side mechanism 110 and the output-side mechanism 120. In addition, the steering assistance device 200 may control the separation/connection mechanism 130.

The steering assistance device 200 may include at least one of an input power 210, a steering control module 220, a steering actuator 230, and a sensor module 240.

The input power 210 may include at least one of DC power and AC power. Here, the DC power may include a battery or the like, but is not limited thereto, and may include any power source capable of providing direct current.

The steering control module 220 may control the operation of at least one of the input power 210, the steering actuator 230, and the sensor module 240.

For example, the steering control module 220 may receive electrical energy from the input power 210 and filter noise included in the electrical energy.

Here, the electrical energy may include at least one of current, voltage, and power, but is not limited thereto, and may include any energy related to electricity.

The steering control module 220 may generate a steering motor control signal based on information (For example, at least one of steering torque information, steering angle information, position information, and vehicle speed information, etc.) provided from each component in the steering system 1 and/or the vehicle.

The steering control module 220 may convert the filtered electrical energy according to the steering motor control signal to generate an assist steering force, and may control the steering actuator 230 (or the steering motor 231) based on the assist steering force.

The steering actuator 230 may assist steering of the steering device 100 by operating based on assist steering force provided from the steering control module 220.

The steering actuator 230 may include at least one of the steering motor 231 and the reducer 232, but is not limited thereto, and may include any device capable of assisting the steering of the steering device.

Here, in the case that the steering actuator 230 includes the steering motor 231, the steering motor 231 may operate based on the assist steering force provided from the steering control module 220 to control the steering of the steering device 100.

Here, if the steering actuator 230 includes the steering motor 231 and the reducer 232, the steering motor 231 may operate based on the assist steering force provided from the steering control module 220, and the reducer 232 may assist steering of the steering device 100 by being operated according to the operation of the steering motor 231.

The steering motor 231 may include at least one of a single winding type steering motor and a dual winding type steering motor, but is not limited thereto, and may include any motor capable of assisting the steering of the steering device.

The steering motor 231 may include at least one motor of a single-phase type motor, a 3-phase type motor, and a 5-phase type motor, but is not limited thereto, and may include any motor capable of assisting the steering of the steering device.

The steering motor 231 may include at least one of a DC motor and an AC motor (e.g., a synchronous motor and/or an induction motor, etc.), but is not limited thereto, and may include any motor capable of assisting the steering of the steering device.

The sensor module 240 may include at least one sensor. Here, the sensor may include at least one of a steering torque sensor 241, a steering angle sensor 242, and a position sensor 243, but is not limited thereto, and may include any sensor capable of measuring the state of the vehicle and the steering state of the vehicle.

The number of steering torque sensors 241 may be one or a plurality. The steering torque sensor 241 may measure the steering torque of the steering wheel and provide steering torque information of the steering wheel to the steering control module 220.

The number of steering angle sensors 242 may be one or a plurality. The steering angle sensor 242 may measure the steering angle of the steering wheel and provide steering angle information of the steering wheel to the steering control module 220.

The position sensors 243 may be one or plural. The position sensor 243 may measure the position of at least one of the position of the input-side mechanism, the position of the output-side mechanism, and the position of the steering motor, and may provide at least one position information of the position information of the input-side mechanism, the position information of the output-side mechanism, and the position information of the steering motor to the steering control module 220.

The steering torque sensor 241, the steering angle sensor 242, and the position sensor 243 may be included in the sensor module as shown, but are not limited thereto, and may be included in at least one of the input-side mechanism 110, the output-side mechanism 120, the disconnect/connect mechanism 130, the steering wheel 140, the wheel 150, the input power 210, the steering control module 220, and a steering actuator 230 (the steering motor 231 and the reduction gear 232), respectively.

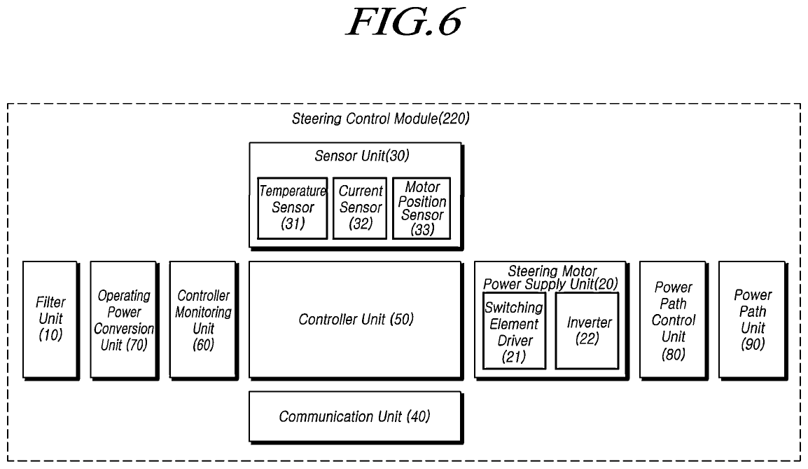

FIG. 6 is a block diagram illustrating a steering control module according to the present embodiments.

Referring to FIG. 6, the steering control module 220 according to the present embodiments may include a filter unit 10, a steering motor power supply unit 20, a sensor unit 30, a communication unit 40, and a controller unit 50, a controller monitoring unit 60, an operating power conversion unit 70, and a power path control unit 80.

The number of filter units 10 may be one or a plurality. The filter unit 10 may be connected to the input power 210. The filter unit 10 may filter noise included in the electrical energy provided from the input power 210 and provide the noise-filtered electrical energy to the steering motor power supply unit 20 and the operating power conversion unit 70.

The steering motor power supply units 20 may be one or plural. The steering motor power supply unit 20 may be connected to the filter unit 10 and receive filtered electrical energy from the filter unit 10.

The steering motor power supply unit 20 may be connected to the controller unit 50 and receive a steering motor control signal from the controller unit 50. The steering motor power supply unit 20 may generate assist steering force by converting the filtered electric energy based on the steering motor control signal, and may control the steering motor 231 based on the assist steering force.

The steering motor power supply unit 20 may include at least one of a switching element driver 21 and an inverter 22.

The switching element driver 21 may receive a steering motor control signal from the controller unit 50, generate a switching element control signal based on the control signal, and provide the control signal to the inverter 22.

The inverter 22 may generate assist steering force by converting the filtered electric energy of the filter unit 10 according to the switching element control signal.

The inverter 22 may include a switch and/or a transistor, but is not limited thereto, and may include any element (or device) capable of generating an assist steering force by converting electrical energy according to a switching element control signal.

Here, in the case that the inverter 22 includes a field effect transistor (FET), the switching element driver 21 may be a gate driver. Accordingly, the gate driver may receive the steering motor control signal from the controller unit 50, generate a gate control signal based on the received steering signal, and provide the gate control signal to the inverter 22. The inverter 22 may generate assist steering force by converting the filtered electrical energy of the filter unit according to the gate control signal.

The number of power path control unit 80 may be one or plural. The power path control unit 80 may be located between the steering motor power supply unit 20 (or inverter 22) and the steering actuator 230 (or steering motor 231), and may supply or cut off the assist steering force provided from the steering motor power supply unit 20 (or the inverter 22) to the steering actuator 230 (or the steering motor 231).

The power path control unit 80 may include at least one phase disconnector(PC0). The phase disconnector is an element or circuit that can cut off a phase, and may include at least one of a switching device, a circuit breaker, a disconnector, a switch, and a transistor, but is not limited thereto, and may include any element or circuit as long as it is capable of cutting off a phase.

The number of power path units 90 may be one or plural. The power path unit 90 may be located between the steering motor power supply unit 20 (or the inverter 22) and the steering actuator 230 (or the steering motor 231) to connect them. Accordingly, the power path unit 90 may provide a power path through which assist steering force may flow from the steering motor power supply unit 20 (or the inverter 22) to the steering actuator 230 (or the steering motor 231).

Meanwhile, the power path control unit 80 may be located on the power path unit 90. Accordingly, the power path control unit 80 may control the power path of the power path unit 90 to supply or block the assist steering force provided from the steering motor power supply unit 20 (or inverter 22) to the steering actuator 230 (or, Steering motor 231).

The sensor unit 30 may include at least one of a temperature sensor 31, a current sensor 32, and a motor position sensor 33, but is not limited thereto, and may include any sensor capable of measuring the state of the steering system (or steering control module).

The temperature sensor 31 may measure the temperature of the steering control module 220 and provide temperature information to the controller unit 50.

The current sensor 32 may measure assist current (or assist steering force) provided from the steering motor power supply unit 20 to the steering actuator 230 (or steering motor 231), and may provide the assist current information to the controller unit 50.

The motor position sensor 33 may measure the position of the steering motor and provide position information of the steering motor to the controller unit 50. The motor position sensor 33 may be included in the steering control module 220, but is not limited thereto, and may be provided separately.

The communication unit 40 may be one or plural. The communication unit 40 may include at least one of an internal communication unit and an external communication unit. In the case that there are a plurality of steering control modules, the internal communication unit may be connected to other steering control modules to receive or provide information to each other. The external communication unit may be connected to the vehicle and receive vehicle state information (e.g., vehicle speed information) from the vehicle, or provide information related to the steering system to the vehicle. The controller unit 50 may be one or plural. The controller unit 50 may be connected to each component of the steering control module 220 to provide or receive information, and control the operation of each component of the steering control module 220 based on the information.

For example, according to at least one information of the steering torque information of the steering wheel, steering angle information of the steering wheel, temperature information, assist current information, position information (position information of the input-side mechanism, position information of the output-side mechanism, and position information of the steering motor, etc.), vehicle state information (e.g., vehicle speed information), state information of the input power, short-circuit (or overcurrent) state information, current detection information of the filter unit, and steering motor state information, the controller unit 50 may generates a steering motor control signal and provide it to the steering motor power supply 20 (or switching element driver 21), or may generate and provide the separation/connection control signal (e.g., clutch control signal) to the separation/connection mechanism.

The controller unit 50 may include a microcontroller, but is not limited thereto, and may include any device (or computer) capable of processing (or executing and calculating) a program.

The controller monitoring unit 60 may be connected to the controller unit 50. The controller monitoring unit 60 may monitor the operating state of the controller unit 50. For example, the controller unit 50 may provide a watchdog signal to the controller monitoring unit 60. In addition, the controller monitoring unit 60 may be cleared based on the watchdog signal provided from the controller unit 50 or may generate a reset signal and provide it to the controller unit 50.

The controller monitoring unit 60 may include a watchdog, but is not limited thereto, and may include any device capable of monitoring the controller unit. In particular, the watchdog may include a window watchdog with a deadline, that is, a start and an end.

The operating power conversion unit 70 may be connected to the filter unit 10. The operating power conversion unit 70 may generate operating voltages for each component of the steering control module 220 by converting the filtered electric energy of the filter unit 10.

The operating power conversion unit 70 may include at least one of a DC-DC converter and a regulator, but is not limited thereto, and may include any device capable of converting the filtered electrical energy to generate an operating voltage for each component of the steering control module and/or the exterior of the steering control module.

Meanwhile, the steering control module 220 may include an electronic control unit (ECU), but is not limited thereto, and may include any control device (or system) capable of electronically controlling.

Meanwhile, the steering actuator 230 may be located on any one of the input-side mechanism 110 and the output-side mechanism 120 to assist the input-side mechanism 110 and the output-side mechanism 120.

For example, in the case that the steering actuator 230 is located on a steering shaft 111 of the input-side mechanism 110, the steering system according to the present embodiments may be in the form of a C-EPS. Alternatively, if the steering actuator 230 is located on the rack 123 of the output-side mechanism 120, the steering system according to the present embodiments may be in the form of an R-EPS. Alternatively, if the steering actuator 230 is located on the pinion 122 of the output-side mechanism 120, the steering system according to the present embodiments may be in the foim of a P-EPS.

Meanwhile, the steering assistance device 200 may be one or plural.

For example, if there are two steering assistance devices 200, the steering assistance device 200 may include an input-side steering assistance device and an output-side steering assistance device.

The input-side steering assistance device may assist the input-side mechanism.

The output-side steering assistance device may assist the output-side mechanism.

Since each of the input-side steering assistance device and the output-side steering assistance device may be understood as the same component as the above-described steering assistance device, it is possible to perform all of the above-described functions in the steering assistance device, and may include all of the components included in the steering assistance device.

For example, the input-side steering assistance device may include at least one of an input-side input power, an input-side steering control module, an input-side steering actuator, and an input-side sensor module. The input-side input power may include at least one power of an input-side DC power and an input-side AC power source. The input-side steering control module may include at least one of an input-side filter unit, an input-side steering motor power supply unit, an input-side sensor unit, an input-side communication unit, an input-side controller unit, an input-side controller monitoring unit, an input-side operation power conversion unit, and an input-side power path control unit. The input-side steering motor power supply unit may include at least one of an input-side switching element driver and an input-side inverter. The input-side sensor unit may include at least one of an input-side temperature sensor, an input-side current sensor, and an input-side motor position sensor.

In addition, the output-side steering assistance device may include at least one of an output-side input power, an output-side steering control module, an output-side steering actuator, and an output-side sensor module. The output-side input power may include at least one power of an output-side DC power and an output-side AC power source. The output-side steering control module may include at least one of an output-side filter unit, an output-side steering motor power supply unit, an output-side sensor unit, an output-side communication unit, an output-side controller unit, an output-side controller monitoring unit, an output-side operation power conversion unit, and an output-side power path control unit. The output-side steering motor power supply unit may include at least one of an output-side switching element driver and an output-side inverter. The output-side sensor unit may include at least one of an output-side temperature sensor, an output-side current sensor, and an output-side motor position sensor.

Here, the input-side sensor module may include at least one of a steering torque sensor, a steering angle sensor and an input-side position sensor, and the output-side sensor module may include an output-side position sensor.

Here, the input-side input power and the output-side input power may be formed as one input power.

Here, all components included in each of the steering assistance device, the input-side steering assistance device, and the output-side steering assistance device may be configured redundantly.

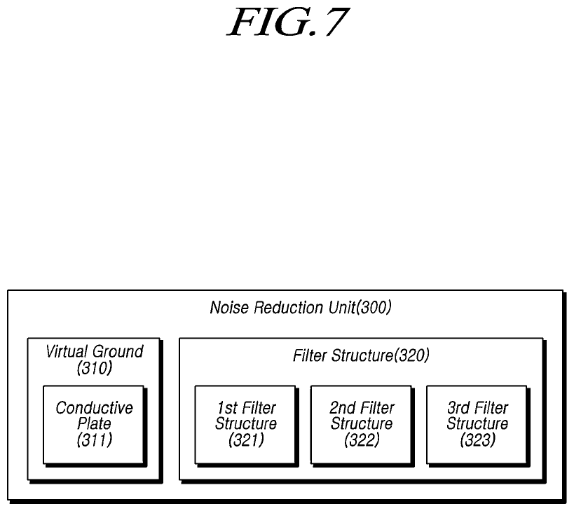

FIG. 7 is a block diagram illustrating a noise reduction device according to the present embodiments.

Referring to FIG. 7, the noise reduction device 300 according to the present embodiments may include at least one of a virtual ground 310 and a filter structure 320.

The virtual ground 310 may include a conductive plate 311.

The filter structure 320 may include at least one of a first filter structure 321, a second filter structure 322, and a third filter structure 323.

Referring to FIGS. 1 to 7, the steering system 1 according to the present embodiments may include the steering assistance device 200 for assisting the steering device 100 positioned between a steering wheel and a wheel, and a noise reduction device 300 (or a noise improvement device) for reducing (or improving) noise of the steering system including the steering assistance device.

The noise may include at least one of noise generated in the steering system, noise flowing into the steering system, and noise flowing out of the steering system, but is not limited thereto, and may include any noise related to the steering system.

The noise may include EMI (electro-magnetic interference) noise, but is not limited thereto, and may include any noise related to the steering system (e.g., EMC (electro-magnetic compatibility) noise and/or EMS (electro-magnetic susceptibility) noise, etc.).

The noise may include common-mode (CM) noise, but is not limited thereto, and may include any noise related to the steering system such as radiated emission (RE) noise, conducted emission (CE) noise, differential-mode (DM) noise, conducted susceptibility (CS) noise, and radiated susceptibility (RS) noise.

The noise may include noise based on a parasitic component present in the steering system, but is not limited thereto, and may include any noise related to the steering system. Referring to FIGS. 1 to 7, the noise reduction device 300 according to the present embodiments may include a virtual ground 310.

The virtual ground 310 may enable a noise path having a lower impedance than a noise path through which noise flows on the steering system to be formed on the steering system. Accordingly, the virtual ground 310 may reduce noise flowing through the steering system.

The virtual ground 310 is not limited by the general definition of virtual and the general definition of ground.

That is, the virtual ground 310 can be understood as a device having a function of reducing noise. Ground may be referred to as earth, ground, or GND.

The virtual ground 310 may be a ground different from the reference ground of the vehicle. The reference ground of the vehicle may be the body of the vehicle.

A noise path may be a place or a path where noise flows. There may be one or multiple noise paths. A noise path may be formed based on at least one parasitic component.

Impedance may mean an impedance value (or magnitude).

For example, the virtual ground 310 may allow a second noise path having a lower impedance than a first noise path through which noise flowing into the steering assistance device flows to be formed on the steering system. Through this, the virtual ground 310 can reduce noise flowing into the steering assistance device.

The first noise path may refer to a reverse noise path through which noise flowing backward into the steering assistance device flows.

The first noise path may be formed based on a parasitic path between the steering device and the steering assistance device.

There may be one or a plurality of first noise paths. There may be one or multiple parasitic paths.

Since the second noise path is different from the first noise path and has a lower impedance than the first noise path, noise flowing into the steering assistance device may flow through the second noise path rather than the first noise path.

In addition, the virtual ground 310 may be located on the steering assistance device to isolate noise introduced through the second noise path and dissipate the isolated noise as heat.

Specifically, the virtual ground 310 may be located on the steering assistance device 200. That is, the virtual ground 310 may be located around (or near) the steering assistance device 200. The virtual ground 310 is located on the steering assistance device 200, so that the second noise path having a lower impedance than the first noise path through which noise flowing into the steering assistance device flows may be formed on the steering system.

Noise flowing into the steering assistance device may flow to the virtual ground 310 through the second noise path.

The virtual ground 310 may isolate noise introduced through the second noise path. The virtual ground 310 can dissipate isolated noise as heat.

In addition, the virtual ground 310 may include, but is not limited to, the conductive plate 311, and may include any component capable of isolating noise and dissipating the isolated noise as heat.

The conductive plate 311 may include a conductor. In particular, the conductor may be a conductor capable of dissipating heat. Here, the conductor capable of dissipating heat may include aluminum, but is not limited thereto.

That is, the conductive plate 311 may include aluminum, however, is not limited thereto, and may include any material capable of isolating noise and dissipating the isolated noise as heat (e.g., a conductor capable of dissipating heat, metal with high thermal conductivity, etc.).

In addition, the virtual ground 310 may be located on the steering assistance device to isolate noise flowing from the steering assistance device and dissipate the isolated noise as heat.

Referring to FIGS. 1 to 7, the noise reduction device 300 according to the present embodiments may include a filter structure 320.

The filter structure 320 may be located between the steering device 100 and the steering assistance device 200, and may filter noise flowing from the steering assistance device.

That is, the filter structure 320 may be positioned between the steering device 100 and the steering assistance device 200 to adjust the impedance between the steering device 100 and the steering assistance device 200, thereby controlling the steering assistance device. The filter structure may block and/or pass noise generated by the steering assistance device from the steering assistance device to the steering device.

The noise may include at least one of AC (or alternating current) noise and DC (or direct current) noise. AC noise can have at least one specific frequency. The specific frequency may be a frequency of noise generated during switching in a steering motor power supply unit (e.g., a transistor included in an inverter).

The filter structure 320 may include at least one of a first filter structure 321, a second filter structure 322, and a third filter structure 323.

The first filter structure 321 may pass DC noise among noise flowing out from the steering assistance device and block AC noise.

That is, the first filter structure 321 may be located between the steering device 100 and the steering assistance device 200 to pass DC noise among the noise generated in the steering assistance device to the steering device and to block AC noise from passing through to the steering device.

That is, the first filter structure 321 may connect the steering device 100 and the steering assistance device 200 in a DC manner and block them in an AC manner.

The first filter structure 321 may include a resistance structure that causes resistance. The resistance structure may include a resistor, but is not limited thereto, and may include any structure capable of causing (or having) resistance (or a structure that passes DC noise and blocks AC noise).

The first filter structure 321, that is, a resistance structure (e.g., a resistor) may include a resistance bushing. Resistance bushings may include a rubber (or synthetic rubber or polyurethane) bushings, but are not limited thereto, and may include any bushing capable of producing (or having) resistance (or bushings that pass DC noise and block AC noise).

The number of first filter structures 321 (e.g., resistors) may be one or plural.

The second filter structure 322 may block AC noise having a specific frequency among noise flowing out from the steering assistance device.

That is, the second filter structure 322 may be located between the steering device 100 and the steering assistance device 200 to block the AC noise having a specific frequency among noise generated by the steering assistance device so as to prevent AC noise having a specific frequency among noise generated by the steering assistance device from passing over to the steering device.

The second filter structure 322 may include an inductance structure which generates inductance. The inductance structure may include, but is not limited to, an inductor, and may include any structure as long as it is a structure that causes (or has) inductance (or a structure that blocks AC noise having a specific frequency).

The second filter structure 322, that is, the inductance structure (e.g., inductor) may include a heli coil, but is not limited thereto, and may include any coil capable of causing (or, having) inductance (or a coil that blocks AC noise with a specific frequency).

The heli coil is a known coil, and may be located between the steering device 100 and the steering assistance device 200 to connect them. That is, by planting a heli coil inside an insulator so that the steering device 100 and the steering assistance device 200 may be electrically connected to each other, thereby generating the inductance (that is, providing an inductance effect). The number of the second filter structures 322 (e.g., inductors) may be one or plural.

The third filter structure 323 may pass AC noise having a specific frequency among noise flowing out from the steering assistance device.

That is, the third filter structure 323 may be positioned between the steering device 100 and the steering assistance device 200 to pass AC noise having a specific frequency among noise generated by the steering assistance device to the steering device.

The third filter structure 323 may include a capacitance structure capable of causing or generating capacitance. The capacitance structure may include, but is not limited to, any structure capable of causing (or generating) capacitance (a structure that passes AC noise having a specific frequency).

The third filter structure 323, that is, a capacitance structure (e.g., a capacitor) may include a feed-thru capacitor. The Feed-thru Capacitor may include a bushing style feed-thru capacitor, but is not limited thereto, and may include any capacitor capable of causing (or having) capacitance (a capacitor that passes AC noise having a specific frequency).

A feed-thru capacitor (for example, a bushing style feed-thru capacitor) is a known capacitor, and may be located between the steering device 100 and the steering assistance device 200 to connect them. That is, capacitance can be generated by planting a feed-thru capacitor (for example, a bushing style feed-thru capacitor) inside the insulator, thereby electrically connecting the steering device 100 and the steering assistance device 200 (i.e., providing the capacitance effect).

The number of third filter structures 323 (e.g., capacitors) may be one or a plurality.

Referring to FIGS. 1 to 7, the noise reduction device 300 according to the present embodiments may include a virtual ground 310 and a filter structure 320.

The virtual ground 310 may allow a second noise path having a lower impedance than the first noise path to flow noise flowing into the steering assistance device to be formed on the steering system. The filter structure 320 may be located between the steering device and the steering assistance device, and may filter noise flowing from the steering assistance device.

Here, since the virtual ground 310 and the filter structure 320 have been described above, the description thereof will be omitted for simplicity of description below.

Referring to FIGS. 1 to 7, the steering assistance device 200 according to the present embodiments may include at least one of a steering actuator 230, a steering motor power supply unit 20, and a filter unit 10.

The steering assistance device 200 may include a steering actuator 230 which includes a steering motor 231 and assists the steering device 100 based on the steering motor, and a steering motor power supply unit 20 which generates assist steering force by converting electric energy based on a steering motor control signal and controls the steering motor based on the assist steering force.

The virtual ground 310 may be located in at least one of the steering motor 231 and the steering motor power supply unit 20. That is, the virtual ground 310 may be located around (or near) at least one of the steering motor 231 and the steering motor power supply unit 20 (e.g., the inverter 22).

In addition, the steering assistance device 200 may include a filter unit 10 which filters noise included in electrical energy provided from the input power and provides the filtered electrical energy to the steering motor power supply unit.

The steering motor power supply unit 20 may generate assist steering force by converting the filtered electric energy based on the steering motor control signal, and control the steering motor based on the assist steering force.

Here, the filter unit 10 may include at least one of a CM noise filter and a DM noise filter. The CM noise filter may include at least one of a CM inductor (or coil) and a Y capacitor. The DM noise filter may include an X capacitor.

The filter unit 10 may use the above-described configuration, but is not limited thereto, and may include any component capable of filtering noise included in electrical energy provided from the input power supply unit or blocking or bypassing incoming noise. Referring to FIGS. 1 to 7, a steering device 100 according to the present embodiments may include an input-side mechanism 110 connected to a steering wheel, and an output-side mechanism 120 connected to the wheel. In addition, the steering assistance device 200 according to the present embodiments may assist at least one of the input-side mechanism 110 and the output-side mechanism 120. The filter structure 320 may be positioned between at least one of the steering motor 231 and the reducer 232 and at least one of the input-side mechanism 110 and the output-side mechanism 120.

For example, if the steering actuator 230 including the steering motor 231 and the reducer 232 is located in the rack of the output-side mechanism (R-EPS type), the filter structure 320 may be positioned between the steering motor 231 and/or the reducer 232 and the rack of the output-side mechanism 120.

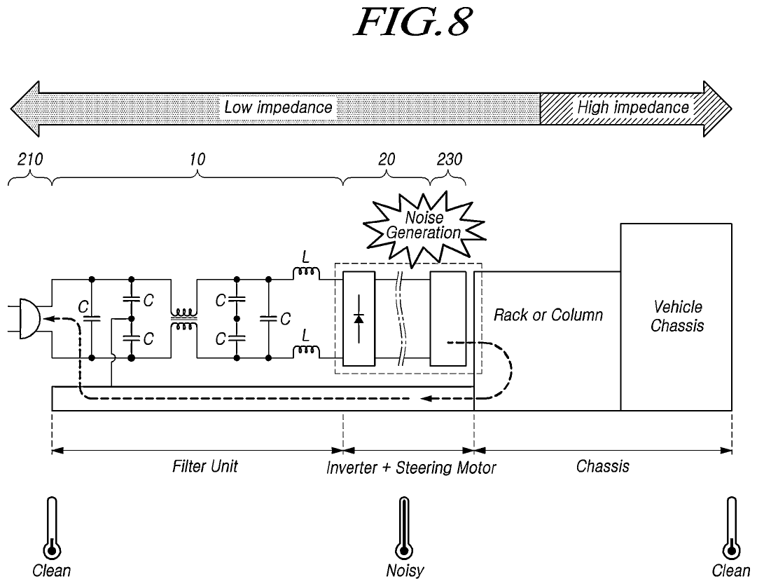

FIG. 8 is a diagram for explaining noise in the steering system according to the present embodiments. Hereinafter, the steering assistance device will be referred to as EPS and described.

Referring to FIG. 8, the EPS according to the present embodiments may be mechanically and firmly fixed to a rack and/or a steering column using bolts, which may be an electrical connection passage. Such a connection method may form an unintentional noise path and become a path through which EMI noise is transferred.

Accordingly, the steering system according to the present embodiments may use a virtual ground and/or an change in electrical connection structure, and may reduce EMI noise transmitted to a parasitic path of the EPS motor driver (i.e., steering assistance device).

Specifically, the EPS according to the present embodiments may reduce noise through the filter unit 10. For example, the EPS according to the present embodiments may reduce CM noise by blocking and/or bypassing a CM path through a filter unit (CM noise filter).

In particular, the CM noise filter according to the present embodiments may block or bypass the CM path through the CM coil and the Y capacitor.

However, a parasitic path is formed from the load (steering motor) to the mechanically connected rack and/or steering column (or EPS Chassis), so that the noise may flow to a reference ground for the vehicle body (or vehicle chassis). However, due to mechanical problems (distance or impedance), the noise may flow back into the filter unit through the first noise path as shown in the figures.

Since the inverter and the steering motor are the main causes of EMI noise and/or EMC noise, there is required to manage through blocking and bypassing from the noise source to the transmission path of the noise. However, in order to manage the parasitic path between the coil of the steering motor and the frame of the steering motor, which is one of the main noise paths, the structure of the steering motor may be modified. However, if the structure of the steering motor is changed, it may affect the performance and structural parts of the steering motor, so design changes may be limited.

Although it is possible to reduce noise from a noise source, there may be more efficient to reduce noise by improving a transmission path of noise rather than a noise source in order to require a fast response speed or to generate low heat depending on circumstances.

Accordingly, the steering system according to the present embodiments may provide a method for improving the noise path. In particular, a virtual reference ground may be formed to selectively create a noise path, thereby improving the noise problem (e.g., EMI noise). In addition, the noise (e.g., EMI noise, etc.) may be improved by applying characteristic structures such as high impedance DC short, inductor, capacitor, etc. to the parasitic path.

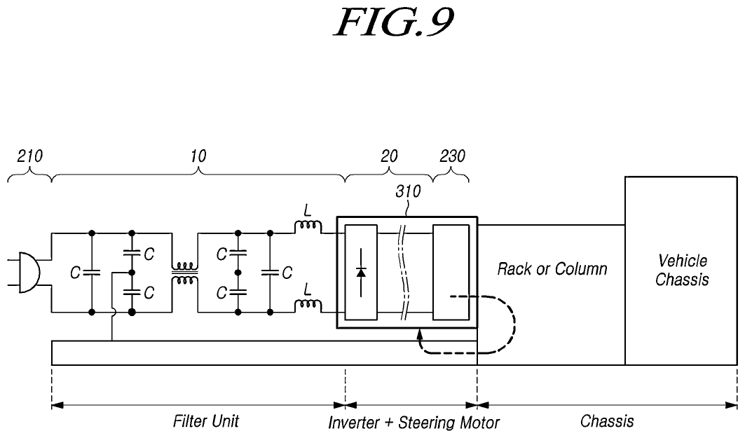

FIG. 9 is a diagram for explaining a noise improvement method using a virtual ground according to the present embodiments.

Referring to FIG. 9, noise may flow in search of a fundamentally low impedance. In this case, if the frequency of the noise is high, since the impedance increases as the path lengthens, the path is required to be short for low impedance design.

As shown in the figure, the structure of the load (steering motor)—rack and/or column—vehicle chassis has low DC resistance, but has high impedance due to the long path at high frequency. Therefore, the noise may be easily reduced by creating a low-impedance path on the other path, forcing that path toward the virtual ground, and emitting the noise as heat or some other form (radiation).

That is, the steering system according to the present embodiments forms a virtual reference ground to selectively create a noise path (e.g., a second noise path shown in the drawing), so that noise characteristic (For example, EMI noise, etc.) can be improved. Here, the virtual reference ground may be referred to as a virtual ground.

The steering system according to the present embodiments may isolate noise transmitted to the inverter and/or steering motor to the virtual ground 310.

In addition, by adding a conductive plate for virtual ground to the inverter and/or steering motor, there may form a lower impedance path than the path flowing back to the chassis or EPS filter.

Accordingly, since the path of the noise removed by the filter unit is not affected, and the noise generated from the inverter and/or the steering motor is separately bypassed, there may be advantageous to manage the noise path. If the virtual ground added in this way is made of a metal with high thermal conductivity such as aluminum, there may be also effective in dissipating heat generated from the EPS.

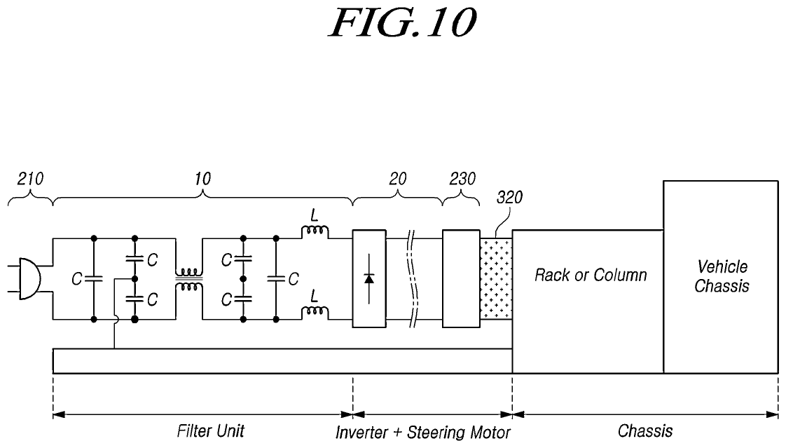

FIG. 10 is a diagram for explaining a noise improvement method using a filter structure according to the present embodiments.

Referring to FIG. 10, the steering system according to the present embodiments may reduce EMI noise based on the filter structure 320 positioned between the steering device and the steering assistance device. That is, the steering system according to the present embodiments may reduce EMI noise by applying a structure having characteristics of a high impedance DC short, an inductor, and a capacitor to a parasitic path.

In the noise improvement method using the filter structure according to the present embodiments, in order to design a noise transmission path as a path through the filter structure, there may provide a method in which the steering motor as a final end is electrically disconnected from the EPS chassis and connected to high impedance DC or AC.

Here, in case of designing the connection between the steering motor and the EPS chassis as a high impedance DC or AC connection, two structures may be connected in DC through a resistive connection (tens of ohms or more), however AC may be blocked by maintaining a high impedance overall, and AC noise may be selectively blocked and bypassed according to frequency through inductor and capacitor.

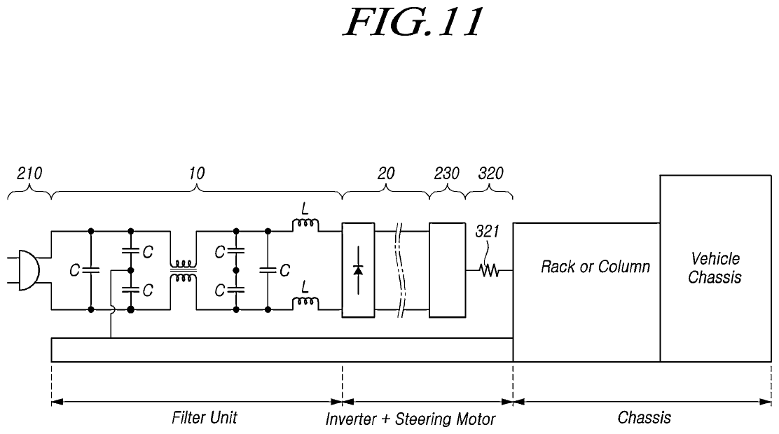

FIG. 11 is a diagram for explaining a noise improvement method using a first filter structure according to the present embodiments.

Referring to FIG. 11, the steering system according to the present embodiments may reduce EMI noise by applying a first filter structure 321, that is, a resistance structure (or high impedance DC short structure) to a parasitic path.

A physical connection between the two structures (steering motor and EPS chassis) may be implemented using a resistive bushing or the like. In this case, not only the path through the EPS chassis is blocked, but also the intended design of the filter unit of the EPS may be possible.

This resistive bushing may be a rubber bush, and since the rubber bush has a high impedance in the overall frequency band, it is effective not only in blocking AC noise but also in vibration of the rack.

In the above-described method, since it is impossible to completely open when connecting the steering motor and/or ECU to the chassis with DC, DC connection is formed through a resistance of about tens of ohms, thereby blocking/passing AC noise.

Though it is described that the AC noise is filtered since the high-frequency side impedance is low, but this is the case of an equivalent model that reflects the parasitic components of general resistance. Therefore, in case of properly combining L and C by adjusting the length, area, component, structure, etc. of the resistive bushing, there may be as a high frequency filter.

In the case that the impedance of DC is several tens of ohms, although it is high, it can be a path where current is generated to some extent, so the impedance of DC may be preferably several tens of ohms [Ω] (e.g., approximately 50 ohms). A few ohms is undesirable since it cause 1 ampere current of 1V (maximum 1 V due to a GND terminal)/1 ohm. In addition, high resistance more than 1k ohm is not preferable since it may cause an open-circuit and float the ECU heat sink.

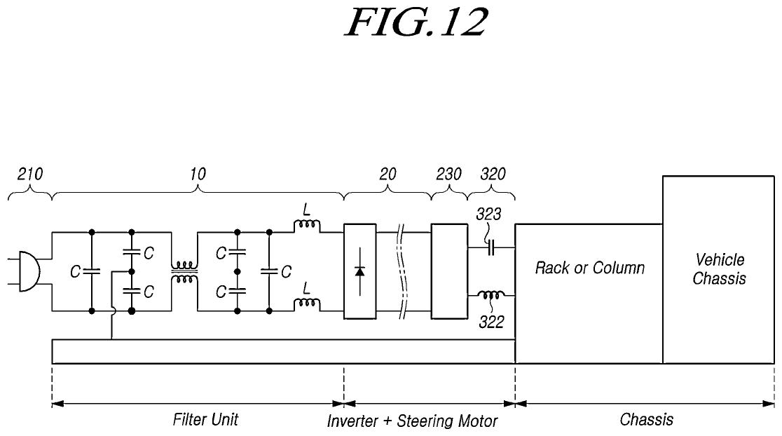

FIG. 12 is a diagram for explaining a noise improvement method using a second filter structure and a third filter structure according to the present embodiments.

Referring to FIG. 12, the steering system according to the present embodiments may reduce EMI noise by applying a second filter structure 322 and a third filter structure 322, that is, a structure having inductor and capacitor characteristics to a parasitic path.

Unlike noise blocking using a resistance structure, an inductance structure and a capacitance structure may block and/or bypass noise for a specific frequency.

The inductance structure, that is, the inductor, may block noise for a specific frequency, and the capacitance structure, that is, the capacitor, on the contrary, may pass the noise for a specific frequency. Accordingly, the noise generated in the EPS can be effectively transferred to or blocked from the EPS chassis by the AC connection.

As described above, the steering system according to the present embodiments may control unintended parasitic paths using a virtual ground and/or electrical connection structure change, thereby effectively coping with EMC and increasing reliability by reducing noise.

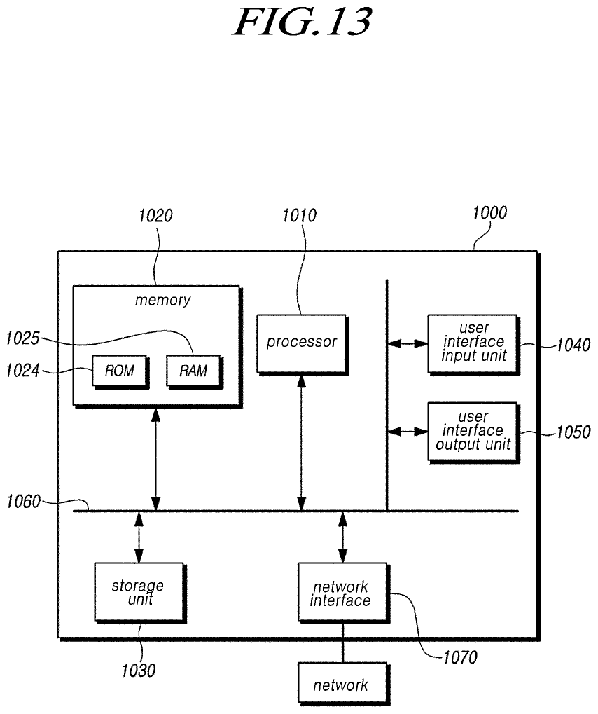

FIG. 13 is a block diagram of a computer system of a steering control device, a steering assistance device, and a steering system according to the present embodiments.

Referring to FIG. 13, the above-described embodiments may be implemented in a computer system, for example, a computer-readable recording medium. As shown in the drawing, a computer system 1000 such as a steering control device (or steering control module), a steering assistance device and a steering system may include at least one element of one or more processors 1010, a memory 1020, a storage unit 1030, a user interface input unit 1040, and a user interface output unit 1050. These elements may communicate with each other via the bus 1060. Further, the computer system 1000 may also include a network interface 1070 for connecting to a network. The processor 1010 may be a CPU or a semiconductor device for executing processing instructions stored in the memory 1020 and/or the storage 1030. The memory 1020 and the storage unit 1030 may include various types of volatile/nonvolatile storage media. For example, the memory may include ROM 1024 and RAM 1025.

Accordingly, the present embodiments may be implemented as a computer-implemented method or a non-volatile computer recording medium having computer-executable instructions stored therein. The instructions, when executed by a processor, may perform the method according to at least one embodiment of the present embodiments. In particular, if there are a plurality of cores, at least one of the plurality of cores may include a lockstep core.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure. Thus, the scope of the present disclosure is not limited to the embodiments shown, but is to be accorded the widest scope consistent with the claims. The scope of protection of the present disclosure should be construed based on the following claims, and all technical ideas within the scope of equivalents thereof should be construed as being included within the scope of the present disclosure.

What is claimed is:

1. A steering system comprising:
a steering assistance device configured to assist a steering device positioned between a steering wheel and a wheel; and
a noise reduction device configured to reduce noise of the steering system including the steering assistance device,
wherein the noise reduction device comprises a virtual ground,
wherein the virtual ground enables a second noise path having a lower impedance than a first noise path through which noise flowing into the steering assistance device flows to be famed on the steering system.

2. The steering system of claim 1, wherein the first noise path is foamed based on a parasitic path between the steering device and the steering assistance device.

3. The steering system of claim 1, wherein the virtual ground is located on the steering assistance device to isolate noise introduced through the second noise path and dissipate the isolated noise as heat.

4. The steering system of claim 1, wherein the virtual ground comprises a conductive plate.

5. The steering system of claim 1, wherein the steering assistance device comprises:
a steering actuator including a steering motor and assisting the steering device based on the steering motor;
a steering motor power supply unit configured to generate an assist steering force by converting electric energy based on a steering motor control signal and control the steering motor based on the assist steering force; and
a filter unit configured to filter noise included in electric energy provided from input power and provide filtered electric energy to the steering motor power supply unit.

6. The steering system of claim 5, wherein the virtual ground is located in at least one of the steering motor and the steering motor power supply unit.

7. The steering system of claim 5, wherein the filter unit comprises at least one of a common-mode (CM) noise filter and a differential-mode (DM) noise filter.

8. A steering system comprising:
a steering assistance device configured to assist a steering device positioned between a steering wheel and a wheel; and
a noise reduction device configured to reduce noise of the steering system including the steering assistance device,
wherein the noise reduction device comprises a filter structure,
wherein the filter structure is located between the steering device and the steering assistance device to filter noise flowing out from the steering assistance device.

9. The steering system of claim 8, wherein the filter structure comprises at least one of,
a first filter structure configured to pass DC noise among noise flowing out from the steering assistance device and block AC noise,
a second filter structure configured to block AC noise having a specific frequency among noises flowing out from the steering assistance device, and
a third filter structure configured to pass AC noise having a specific frequency among noises flowing out from the steering assistance device.

10. The steering system of claim 9, wherein the first filter structure comprises a resistance structure generating resistance, the second filter structure comprises an inductance structure generating inductance, and the third filter structure comprises a capacitance structure generating capacitance.

11. The steering system of claim 9, wherein the first filter structure comprises a rubber bushing.

12. The steering system of claim 8, wherein the steering assistance device comprises:
a steering actuator including a steering motor and assisting the steering device based on the steering motor;
a steering motor power supply unit configured to generate an assist steering force by converting electric energy based on a steering motor control signal and control the steering motor based on the assist steering force; and
a filter unit configured to filter noise included in electric energy provided from input power and provide filtered electric energy to the steering motor power supply unit.

13. The steering system of claim 12, wherein the filter unit comprises at least one of a common-mode (CM) noise filter and a differential-mode (DM) noise filter.

14. A steering system comprising:
a steering assistance device configured to assist a steering device positioned between a steering wheel and a wheel; and
a noise reduction device configured to reduce noise of the steering system including the steering assistance device,
wherein the noise reduction device comprises a virtual ground and a filter structure,
wherein the virtual ground enables a second noise path having a lower impedance than a first noise path through which noise flowing into the steering assistance device flows to be famed on the steering system,
wherein the filter structure is located between the steering device and the steering assistance device to filter noise flowing out from the steering assistance device.

15. The steering system of claim 14, wherein the first noise path is famed based on a parasitic path between the steering device and the steering assistance device.

16. The steering system of claim 14, wherein the virtual ground is disposed on the steering assistance device to isolate noise introduced through the second noise path and dissipate the isolated noise as heat.

17. The steering system of claim 14, wherein the virtual ground comprises a conductive plate.

18. The steering system of claim 14, wherein the filter structure comprises at least one of,
a first filter structure configured to pass DC noise among noise flowing out from the steering assistance device and block AC noise,
a second filter structure configured to block AC noise having a specific frequency among noises flowing out from the steering assistance device, and
a third filter structure configured to pass AC noise having a specific frequency among noises flowing out from the steering assistance device.

19. The steering system of claim 18, wherein the first filter structure comprises a resistance structure generating resistance, the second filter structure comprises an inductance structure generating inductance, and the third filter structure comprises a capacitance structure generating capacitance.

20. The steering system of claim 18, wherein the first filter structure comprises a rubber bushing.
